(19) United States
(12) Patent Application Publication
(10) Pub. No.: US 2015/0357361 A1
(43) Pub. Date: Dec. 10, 2015

(54) IMAGING DEVICE

(71) Applicant: V TECHNOLOGY CO., LTD., Kanagawa (JP)

(72) Inventors: Koichi Kajiyama, Kanagawa (JP); Michinobu Mizumura, Kanagawa (JP); Masayasu Kanao, Kanagawa (JP); Shin Ishikawa, Kanagawa (JP)

(73) Assignee: V TECHNOLOGY CO., LTD., Kanagawa (JP)

(21) Appl. No.: 14/759,278

(22) PCT Filed: Dec. 10, 2013
(86) PCT No.: PCT/JP2013/083032

§ 371 Date: Jul. 6, 2015

(30) Foreign Application Priority Data
Jan. 8, 2013 (JP) 2013-001399

(51) Int. Cl. H01L 27/146

(52) U.S. Cl. CPC H01L 27/14607; H01L 27/14645; H01L 27/14649

(57) ABSTRACT

When a visible light image and an image of a long-wavelength region with a near-infrared wavelength or longer are acquired using one imaging sensor, a clear image of the long-wavelength region with the near-infrared wavelength or longer is obtained. In an imaging sensor 1 in an imaging device, a plurality of photoelectric conversion parts 2 (2A, 2B) are formed on one semiconductor substrate 10. The respective photoelectric conversion parts 2A in a group of the plurality of photoelectric conversion parts 2 (2A, 2B) exhibit spectral sensitivity characteristics that peak in a long-wavelength region with a near-infrared wavelength or longer. The plurality of photoelectric conversion parts 2 (2A, 2B) include photoelectric conversion parts 2B exhibiting spectral sensitivity characteristics that peak in a visible light region.

### TECHNICAL FIELD

The invention relates to an imaging device having an imaging sensor.

### BACKGROUND ART

An imaging device is known, which includes an imaging element that has sensitivity to near-infrared light and visible light. Patent Literature 1 listed below describes an imaging device including a color filter that is placed on a solid state imaging element with sensitivity to infrared light and visible light and that transmits near-infrared light, and position adjusting means for adjusting the position of an infrared cut filter arranged in front of the color filter.

Patent Literature 2 listed below describes a solid state imaging element including a pixel with a color filter arranged therein that transmits wavelengths for both red light and green light, a pixel with a color filter arranged therein that transmits wavelengths for both blue light and green light, a pixel with a color filter arranged therein that transmits wavelengths for both near-infrared light and green light, and a pixel with a color filter arranged therein that transmits a wavelength only for near-infrared light.

Patent Literature 3 listed below describes an imaging sensor with a plurality of photoelectric conversion parts arranged therein that has sensitivity to a range from a visible light region to an infrared light region, in which the plurality of photoelectric conversion parts include a first group with a red transmission filter arranged therein, a second group with a green transmission filter arranged therein, a third group with a blue transmission filter arranged therein, and a fourth group with an infrared light transmission filter arranged therein.

### RELATED ART LITERATURE

### Patent Literature

[Patent Literature 1] Japanese Patent Application Laid-open No. 2000-59798
[Patent Literature 2] Japanese Patent Application Laid-open No. 2009-253447
[Patent Literature 3] Japanese Patent Application Laid-open No. 2010-62604

### SUMMARY

In the above-described related arts, in the imaging sensor (solid state imaging element) with the plurality of photoelectric conversion parts, each photoelectric conversion part has sensitivity to light ranging from the visible light region to the near-infrared light region so that the sensitivity of the photoelectric conversion part to the near-infrared region is used to obtain an image of near-infrared light. Thus, near a limiting wavelength on a long-wavelength side, a near-infrared image is obtained at a low sensitivity. This precludes a clear near-infrared image from being obtained.

Moreover, in all of the above-described related arts, light is incident on the photoelectric conversion part via the color filter or the infrared transmission filter. Thus, an output from the photoelectric conversion part is forced to be the sum of the optical transmission characteristics (spectral transmission factor characteristics) of the color filter or the infrared transmission filter and the sensitivity characteristics (spectral sensitivity characteristics) of the photoelectric conversion part, preventing the long-wavelength side spectral sensitivity characteristics of the photoelectric conversion part from being sufficiently utilized. This also precludes a clear near-infrared image from being obtained.

Furthermore, when a filter position is adjusted to switch between acquisition of a visible light image and acquisition of a near-infrared image as in the related art described in Patent Literature 1, the filter cannot be adjusted to respond to a changing situation, for example, if, during nighttime, an imaging target irradiated with lighting and an imaging target irradiated with no lighting are image-captured in real time. This precludes images from being obtained.

In one or more embodiments of the invention clear images of a long-wavelength region with a near-infrared wavelength or longer may be obtained when a visible light image and the image with the long-wavelength region with the near infrared wavelength or longer are acquired using one imaging sensor and may enable an image to be image-captured in real time during nighttime, for example, when lighting changes.

An imaging device according to one or more embodiments of the invention may have the following configuration.

An imaging device including an imaging sensor having a plurality of photoelectric conversion parts formed on one semiconductor substrate, wherein respective photoelectric conversion parts in a group of photoelectric conversion parts in the plurality of photoelectric conversion parts exhibit spectral sensitivity characteristics that peak in a long-wavelength region with a near-infrared wavelength or longer.

### Advantageous Effects

An imaging device in accordance with one or more embodiments of the invention may include photoelectric conversion parts each exhibiting the spectral sensitivity characteristics that peak in the long-wavelength region with the near-infrared wavelength or longer are formed on one semiconductor substrate as a group of photoelectric conversion parts. Thus, imaging in the long-wavelength region can be achieved at a high sensitivity without the need for a filter, resulting in clear long-wavelength region images of the long-wavelength region with the near-infrared wavelength or longer.

Furthermore, images of the long-wavelength region with the near-infrared wavelength or longer can be obtained with using a group of photoelectric conversion parts without adjustment of a filter or the like, and thus, imaging can be achieved in real time during nighttime when a situation such as lighting changes.

### BRIEF DESCRIPTION OF DRAWINGS

FIGS. 1a-1b show diagrams depicting a configuration example of an imaging sensor in an imaging device in accordance with one or more embodiments of the invention. FIG. 1(a) depicts a planar configuration, and FIG. 1(b) depicts a cross-sectional configuration of one photoelectric conversion part.

FIGS. 2a-2c show diagrams illustrating an example of spectral sensitivity characteristics of the photoelectric conversion part in accordance with embodiments of the present invention.

FIG. 3 is a diagram illustrating an example of steps of forming a group of photoelectric conversion parts in accordance with embodiments of the present invention.

FIGS. 4a-4b show diagrams illustrating another form example of the imaging sensor in the imaging device in accordance with embodiments of the invention.

FIG. 5 is a diagram illustrating another form example of the imaging sensor in the imaging device in accordance with embodiments of the invention.

FIGS. 6a-6b show diagrams (cross-sectional view) illustrating a specific configuration example of the imaging sensor in the imaging device in accordance with embodiments of the invention.

FIGS. 7a-7c show diagrams depicting a system configuration of the imaging device in accordance with embodiments of the invention.

### DESCRIPTION OF EMBODIMENTS

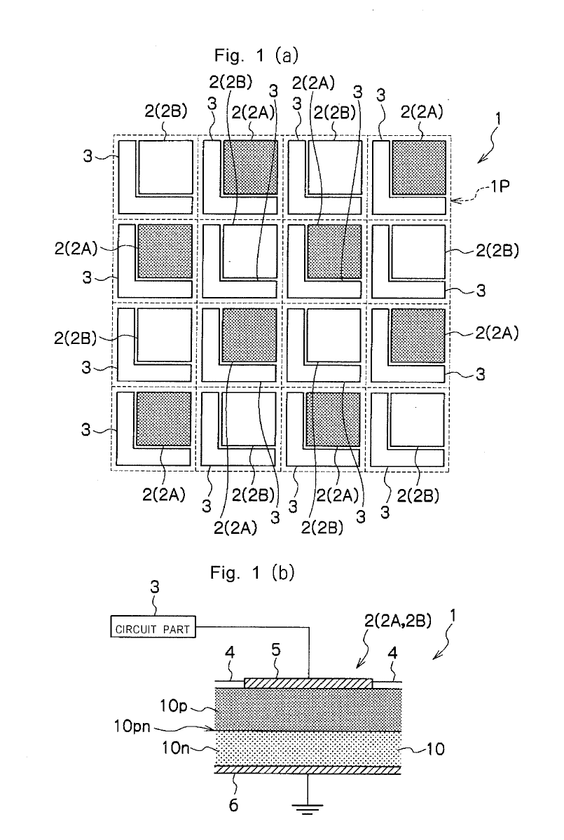

An embodiment of the present invention is described below with reference to the drawings. FIG. 1 is a diagram depicting a configuration example of an imaging sensor in an imaging device in accordance with an embodiment of the invention. FIG. 1(a) depicts a planar configuration, and FIG. 1(b) depicts a cross-sectional configuration of one photoelectric conversion part. In an imaging sensor 1 in the imaging device in accordance with embodiments of the invention, a plurality of photoelectric conversion parts 2 (2A, 2B) are formed on one semiconductor substrate 10. In an example illustrated in FIG. 1, the plurality of photoelectric conversion parts 2 (2A, 2B) are arranged in vertical and horizontal directions in a two-dimensional array (dot matrix) form. One photoelectric conversion part 2 (2A, 2B) corresponds to a pixel 1P in an image image-captured by the imaging sensor 1.

In the imaging sensor 1, respective photoelectric conversion parts in a group of photoelectric conversion parts 2A in the plurality of photoelectric conversion parts 2 (2A, 2B) exhibit spectral sensitivity characteristics that peak in a long-wavelength region with a near-infrared wavelength or longer. The imaging sensor 1 in the illustrated example has the photoelectric conversion parts 2B exhibiting the spectral sensitivity characteristics that peak in the visible light and included in the plurality of photoelectric conversion parts 2 (2A, 2B). Respective plurality of photoelectric conversion parts 2 (2A, 2B) is provided with a circuit part 3 that outputs a light reception signal from the photoelectric conversion part 2 (2A, 2B). In the example illustrated in FIG. 1, one of the two adjacent pixels belongs to the group of photoelectric conversion parts 2A exhibiting the spectral sensitivity characteristics that peak in the long-wavelength region with the near-infrared wavelength or longer.

The photoelectric conversion part 2 (2A, 2B) includes a pn junction part 10pn formed on the semiconductor substrate 10. The semiconductor substrate 10 is, for example, an n-type Si substrate doped with a first material. The n-type Si substrate 10n is doped with a second material to form a p-type semiconductor layer 10p. The pn junction part 10pn is formed at a boundary portion between the n-type Si substrate 10n and the p-type semiconductor layer 10p. In the illustrated example, an electrode (anode) 5 partitioned with an insulation film (transparent insulation film) 4 is provided on a front surface side of the photoelectric conversion part 2 (2A, 2B). A grounded electrode (cathode) 6 is provided on a rear surface side of the photoelectric conversion part 2 (2A, 2B). The electrode (anode) 5 is connected to the circuit part 3. In the illustrated example, the individual photoelectric conversion parts 2 (2A, 2B) are not isolated. However, the present embodiment is not limited to this, and the individual photoelectric conversion parts 2 (2A, 2B) may be isolated from one another using insulating layers or groove spaces.

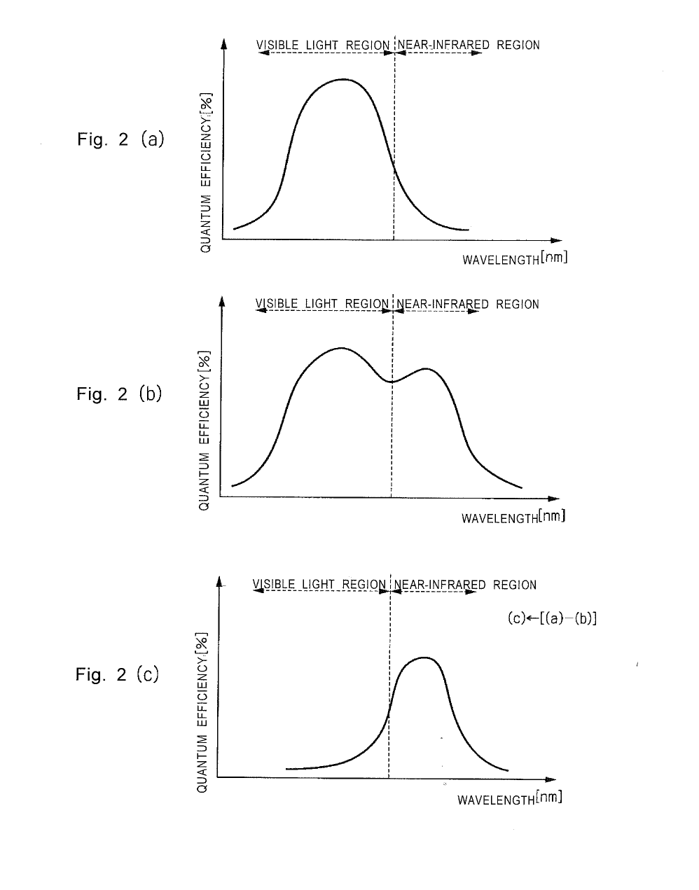

In the imaging device with the imaging sensor 1 described above, the photoelectric conversion parts 2A, 2B with different spectral sensitivity characteristics are formed on one semiconductor substrate 10. FIG. 2 is a diagram illustrating an example of the spectral sensitivity characteristics of the photoelectric conversion parts 2A, 2B. The spectral sensitivity characteristics can be expressed on a graph with an abscissas indicating wavelength [nm] and an ordinate indicating quantum efficiency [%]. FIG. 2(a) depicts the spectral sensitivity characteristics of the photoelectric conversion part 2B. FIG. 2(b) depicts the spectral sensitivity characteristics of the photoelectric conversion part 2A.

As depicted in FIG. 2(a), the photoelectric conversion part 2B exhibits spectral sensitivity characteristics that peak in a visible light region. In contrast, as depicted in FIG. 2(b), the group of photoelectric conversion parts 2A in the plurality of photoelectric conversion parts 2 exhibit spectral sensitivity characteristics that peak in a long-wavelength region with a near-infrared wavelength or longer. The example in FIG. 2(b) illustrates the spectral sensitivity characteristics that peak in the visible light region and also in the long-wavelength region with the near-infrared wavelength or longer. An output of spectral sensitivity characteristics that peak only in the long-wavelength region with the near-infrared wavelength or longer as depicted in FIG. 2(c) can be obtained by subtracting an output from the photoelectric conversion part 2B with the spectral sensitivity characteristics depicted in FIG. 2(a) from an output from the photoelectric conversion part 2A with the spectral sensitivity characteristics depicted in FIG. 2(b). By working out outputs of photoelectric conversion parts 2A and 2B through arithmetic processing, it is possible to obtain the same effect as that obtained by a photoelectric conversion part exhibiting spectral sensitivity characteristics that peak in a long-wavelength region with a near-infrared wavelength or longer as shown in FIG. 2(c).

When the photoelectric conversion parts 2A, 2B exhibiting the different spectral sensitivity characteristics are formed on the one semiconductor substrate 10 as described above, the formation can be achieved by changing dope conditions for the first material and the second material doped into the semiconductor substrate 10 in order to form the pn junction part 10pn.

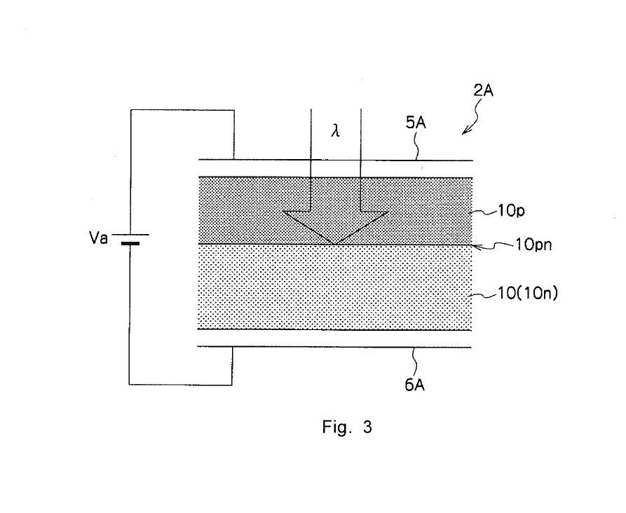

FIG. 3 is a diagram illustrating an example of steps of forming the above-described group of photoelectric conversion parts 2A. The photoelectric conversion part 2A in the semiconductor substrate 10 is formed as follows. First, a Si (silicon) substrate is used as the semiconductor substrate 10. The Si substrate is doped with the first material selected from group 15 elements, for example, As (arsenic), P (phosphor), and Sb (antimony) to form an n-type substrate 10n. The second material is doped into the n-type Si substrate to form the p-type semiconductor layer 10p.

Silicon (Si) is an indirect bandgap semiconductor that features low quantum efficiency, and does not exhibit useful light reception sensitivity by merely forming the pn junction part thereto. However, when the Si substrate 10n is annealed using phonons to generate dressed photons near the pn junction part to allow Si, which is an indirect bandgap semiconductor, to apparently change like a direct bandgap semiconductor, a high-efficiency high-output pn junction light receiving function is achieved.

More specifically, an n-type Si substrate 10n doped with a first material selected from group 15 elements, for example, As (arsenic), P (phosphor), and Sb (antimony) is doped, at a high concentration, with a second material selected from group 13 elements, for example, B (boron), Al (aluminum), and Ga (gallium) to form a p-type semiconductor layer 10p. Then, a first electrode 5A and a second electrode 6A that are transparent electrodes are formed so as to sandwich the pn junction part 10pn between the electrodes 5A and 6A. A forward voltage Va is applied to the first electrode 5A to pass a current between the first electrode 5A and the second electrode 6A through the pn junction part 10pn so as to subject the p-type semiconductor layer 10p to an anneal treatment using Joule heat resulting from the current.

During the anneal treatment, while the second material selected from the group 13 elements, for example, B (boron), Al (aluminum), and Ga (gallium) is being diffused, light with a particular wavelength λ is radiated to the pn junction part 10pn. Radiation of light during the anneal process enables dressed photons to be generated near the pn junction part 10pn. The pn junction part 10pn near which dressed photons are generated exhibits spectral sensitivity characteristics with a peak of quantum efficiency at the wavelength λ of the radiated light. At this time, exemplary dope conditions used when B (boron) is selected as the second material, which is a group 13 element, are a dose density of 5*10¹³/cm² and an acceleration energy during implantation of 700 keV.

To obtain a photoelectric conversion part 2A exhibiting the spectral sensitivity characteristics that peak in the long-wavelength region with the near-infrared wavelength or longer, the wavelength λ of the radiated light in the anneal process is specified to be in the long-wavelength region with the near-infrared wavelength or longer. Furthermore, to obtain a photoelectric conversion part 2B exhibiting the spectral sensitivity characteristics that peak in the visible light region, the wavelength λ of the radiated light in the anneal process is specified to be in the visible light region. In this manner, the wavelength of the radiated light in the anneal process is varied to allow the photoelectric conversion parts 2A, 2B with different spectral sensitivity characteristics to be formed on the one semiconductor substrate 10. In the illustrated example, the individual photoelectric conversion parts 2 (2A, 2B) are not isolated from one another. However, the photoelectric conversion parts 2 (2A, 2B) may be isolated from one another using insulating layers or groove spaces.

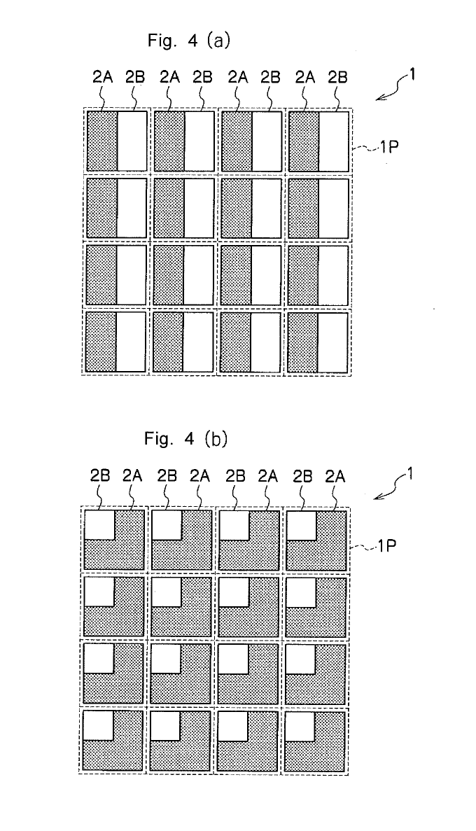

FIG. 4 is a diagram depicting another form example of the imaging sensor in accordance with embodiments of the invention. In FIG. 4, the illustration of the above-described circuit part is omitted. In the example illustrated in FIGS. 4(a), 4(b), a set of a plurality of the photoelectric conversion parts 2 (2A, 2B) corresponds to pixels 1P in an image image-captured by the imaging sensor 1, and one photoelectric conversion part in the pixels 1P corresponds to a group of the photoelectric conversion parts 2A exhibiting the spectral sensitivity characteristics that peak in the long-wavelength region with the near-infrared wavelength or longer.

In the example illustrated in FIG. 4(a), the photoelectric conversion parts 2A exhibiting the spectral sensitivity characteristics that peak in the long-wavelength region with the near-infrared wavelength or longer are arranged in juxtaposition with the photoelectric conversion parts 2B exhibiting the spectral sensitivity that peaks in the visible light region. The two photoelectric conversion parts 2A, 2B provide one pixel 1P. In the example illustrated in FIG. 4(b), in one pixel 1P, the photoelectric conversion part 2A exhibiting the spectral sensitivity characteristics that peak in the long-wavelength region with the near-infrared wavelength or longer has a relatively large light receiving area. The photoelectric conversion part 2B exhibiting the spectral sensitivity that peaks in the visible light region has a relatively small light receiving area. To increase the amount of light received that is in the long-wavelength region with the near-infrared wavelength or longer, it is effective to provide the photoelectric conversion part 2A with a relatively large light receiving area as depicted in FIG. 4(b).

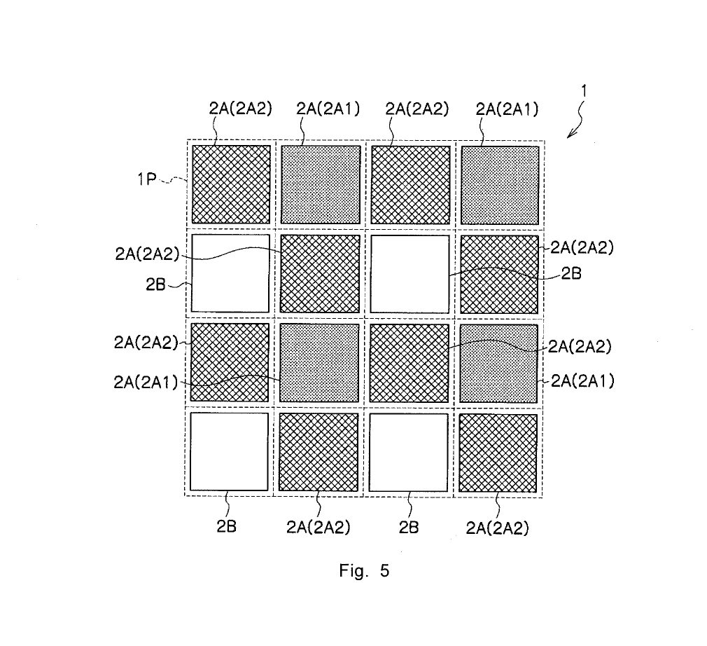

FIG. 5 is a diagram illustrating another form example of the imaging sensor in accordance with embodiments of the invention. In FIG. 5, the illustration of the above-described circuit part is omitted. In the example illustrated in FIG. 5, the photoelectric conversion parts 2 are arranged in the respective pixels 1P. The above-described group of photoelectric conversion parts 2A has photoelectric conversion parts 2A1 exhibiting spectral sensitivity characteristics that peak in a near-infrared region and photoelectric conversion parts 2A2 exhibiting spectral sensitivity characteristics that peak in an intermediate-infrared region. That is, in the imaging sensor 1, the photoelectric conversion parts 2B with a sensitivity peak in the visible light region (400 to 780 nm), the photoelectric conversion parts 2A1 with a sensitivity peak in the near-infrared region (780 to 2600 nm), and the photoelectric conversion parts 2A2 with a sensitivity peak in the intermediate-infrared region (2600 to 3000 nm) are present in the plurality of pixels 1P in a mixed manner.

In the example illustrated in FIG. 5, the photoelectric conversion parts 2B, 2A1 allow a shape image of an observation object to be image-captured, while the photoelectric conversion parts 2A2 simultaneously allow a temperature distribution image of the observation object to be image-captured. To obtain the photoelectric conversion parts 2A2 with a sensitivity peak in the intermediate-infrared region, the wavelength □ of the radiated light in the anneal process during the formation process illustrated in FIG. 3 is specified to be in the intermediate-infrared region.

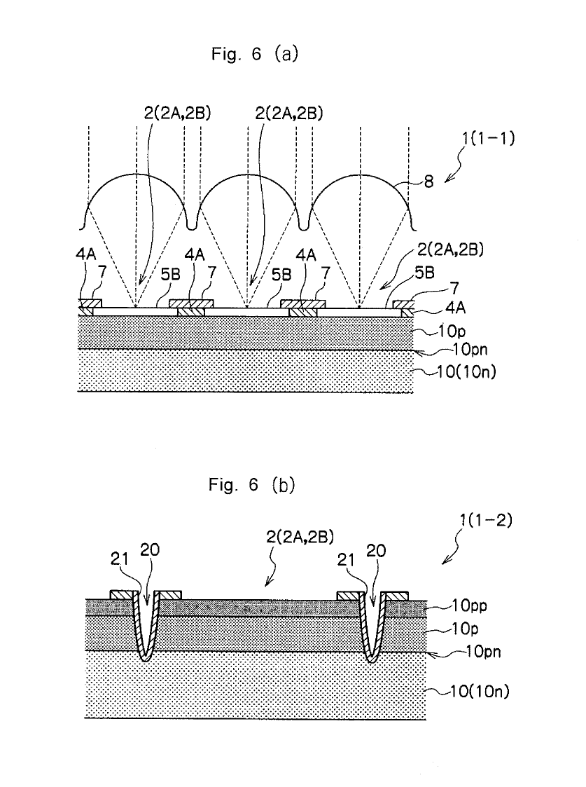

FIG. 6 is a diagram (cross-sectional view) illustrating an example of configuration of the imaging sensor in accordance with embodiments of the present invention. In the imaging sensor 1 (1-1) depicted in FIG. 6(a), the p-type semiconductor layer 10p is formed on the n-type Si substrate 10n (semiconductor substrate 10), which is connected to a cathode, to form the pn junction part 10pn. Electrodes (transparent electrode; anode) 5B partitioned with an insulation film 4A are provided on the p-type semiconductor layer 10p to form the photoelectric conversion parts 2 (2A, 2B). On a front surface side of the photoelectric conversion part 2 (2A, 2B), a light shielding film 7 is provided on the insulation film 4A, and a micro-lens 8 is deployed so as to cover the light shielding film 7 and the electrodes 5B.

In the imaging sensor 1 (1-2) depicted in FIG. 6(b), the photoelectric conversion part 2 (2A, 2B) provides an avalanche photo diode (APD). In the photoelectric conversion part 2 (2A, 2B), the p-type semiconductor layer 10p is formed on the n-type Si substrate 10n to provide a light absorbing layer. A mesa groove 20 is formed so as to surround the anode area on an upper surface of the substrate, and a mesa protecting oxide film 21 is formed on an inner surface of the mesa groove 20 to separate the anode region. Then, a p-type high concentration diffusion layer (p+ layer) 10pp is formed in a front layer of the p-type semiconductor layer 10p to serve as an anode, while the n-type Si substrate 10n serves as a cathode. A single APD is formed for each photoelectric conversion part 2 (2A, 2B).

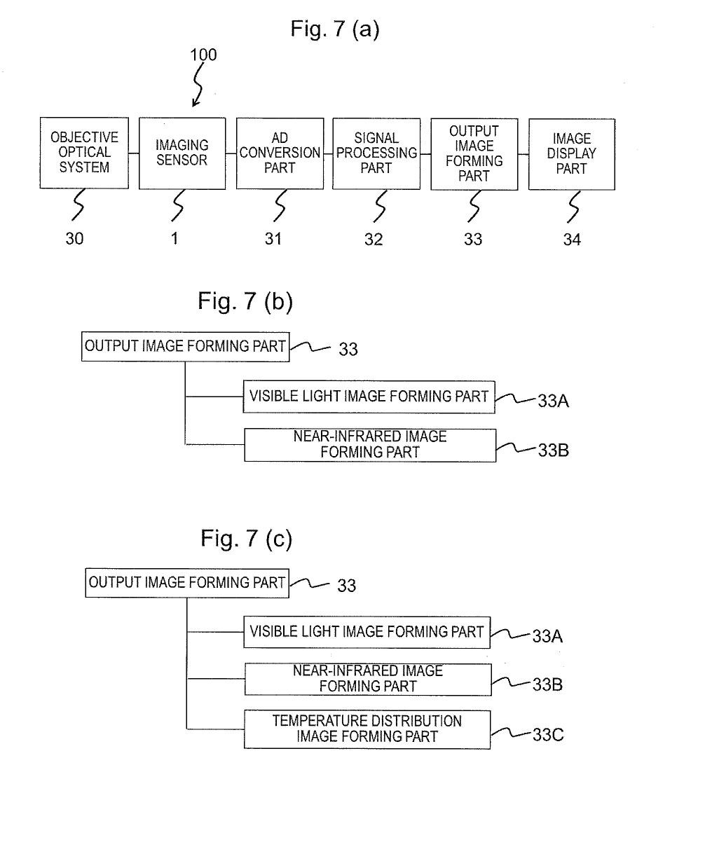

FIG. 7 is a diagram depicting a system configuration of the imaging device in accordance with embodiments of the invention. As depicted in FIG. 7(a), an imaging device 100 includes an objective optical system 30, the above-described imaging sensor 1, an AD conversion part 31, a signal processing part 32, an output image forming part 33, and an image display part 34.

The objective optical system 30 includes an objective lens that forms light (including visible light, near-infrared rays, and intermediate-infrared rays) containing information on the shape of the observation object or temperature into an image in the photoelectric conversion part 2 in the imaging sensor 1. The imaging sensor 1 is as described above and includes the photoelectric conversion parts 2 (2A, 2B). The AD conversion part 31 converts an analog signal output by the imaging sensor 1 into a digital signal, and outputs the digital signal to the signal processing part 32. The signal processing part 32 executes signal processing such as amplification, noise removal, and various corrections on a digital conversion output from the imaging sensor 1, and outputs the resultant signal to the output image forming part 33. The output image forming part 33 uses an image signal resulting from the signal processing to form an output image. The image display part 34 includes a display that displays the output image formed.

The output image forming part 33 in the imaging device 100 with the imaging sensor 1 depicted in FIG. 1 or FIG. 4 includes a visible light image forming part 33A and a near-infrared image forming part 33B as depicted in FIG. 7(b). The visible light image forming part 33A forms a visible light image using the image signal obtained from the photoelectric conversion part 2B exhibiting the spectral sensitivity characteristics that peak in the visible light region. The near-infrared image forming part 33B forms a near-infrared image using the image signal obtained from the photoelectric conversion part 2A exhibiting the spectral sensitivity characteristics that peak in the long-wavelength region with the near-infrared wavelength or longer. Furthermore, the near-infrared image forming part 33B works out a difference between the image signal obtained from the photoelectric conversion part 2B exhibiting the spectral sensitivity characteristics that peak in the visible light region and the image signal obtained from the photoelectric conversion part 2A exhibiting the spectral sensitivity characteristics that peak in the long-wavelength region with the near-infrared wavelength or longer, thereby enabling an image only of the near-infrared region to be formed.

The output image forming part 33 in the imaging device 100 with the imaging sensor 1 depicted in FIG. 5 includes the visible light image forming part 33A, the near-infrared image forming part 33B, and a temperature distribution image forming part 33C as depicted in FIG. 7(c). As described above, the visible light image forming part 33A forms a visible light image using the image signal obtained from the photoelectric conversion part 2B exhibiting the spectral sensitivity characteristics that peak in the visible light region. The near-infrared image forming part 33B forms a near-infrared image using the image signal obtained from the photoelectric conversion part 2A1 exhibiting the spectral sensitivity characteristics that peak in the near-infrared region (780 to 2600 nm) The temperature distribution image forming part 33C forms a temperature distribution image using the image signal obtained from the photoelectric conversion part 2A2 exhibiting the spectral sensitivity characteristics that peak in the intermediate-infrared region (2600 to 3000 nm).

A known scheme may be adopted as a driving scheme for the above-described imaging sensor 1. For example, a CCD scheme or a CMOS scheme may be adopted.

In the imaging device according to embodiments of the invention described above, in the imaging sensor 1, the photoelectric conversion part 2A exhibiting the spectral sensitivity characteristics that peak in the long-wavelength region with the near-infrared is arranged in a distributed manner in the photoelectric conversion parts 2 (2A, 2B) formed in a two-dimensional array on the one semiconductor substrate 10. This serves to effectively expand the spectral sensitivity characteristics of the imaging sensor 1 to longer wavelengths. Thus, a clear image of the long-wavelength region with the near-infrared wavelength or longer can be obtained using the one imaging sensor 1.

Furthermore, in the imaging sensor 1, the photoelectric conversion parts 2B with a peak sensitivity in the visible light region and the photoelectric conversion parts 2A with a peak sensitivity on the long-wavelength side with the near-infrared wavelength or longer are arranged on the one semiconductor substrate 10 in a distributed manner. Thus, a sensor is provided which has a high sensitivity covering a range from the visible light region to the long-wavelength region with the near-infrared wavelength or longer. In this case, utilization of the difference in spectral sensitivity characteristics between the photoelectric conversion parts 2A and 2B eliminates the need for a filter or adjustment of the filter and increases the amount of light incident on each pixel (each photoelectric conversion part 2). Therefore, a sensor can be obtained which has a high photoelectric conversion efficiency and a high sensitivity in spite of a simple structure.

Moreover, the one imaging sensor 1 enables simultaneous acquisition of an image of the visible light region and an image of the long-wavelength region with the near-infrared wavelength or longer. Thus, for example, when a moving object is observed during nighttime when a lighting condition changes or in bad weather when a weather condition changes, the visible light image and the image of the long-wavelength region with the near-infrared wavelength or longer can be displayed while being switched over therebetween in real time.

The embodiments of the invention have been described above in detail with reference to the drawings. However, specific configurations are not limited to these embodiments and the invention includes changes in design that are made without departing from the spirits of the invention. Moreover, the embodiments of the invention may be combined by appropriating the technology of some of the embodiments to those of the other embodiments as long as no contradiction or problem arises in terms of constitutions of the invention.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATION OF REFERENCE NUMERALS

1: imaging sensor, 100: imaging device,
2, 2A, 2B, 2A1, 2A2: photoelectric conversion part,
3: circuit part, 4, 4A: insulation film, 5, 5A, 6, 6A: electrode,
7: light shielding film, 8: micro-lens,
10: semiconductor substrate, 10n: n-type Si substrate, 10p: p-type semiconductor layer,
10pn: pn junction part

1. An imaging device comprising an imaging sensor having a plurality of photoelectric conversion parts formed on one semiconductor substrate, wherein
respective photoelectric conversion parts in a group of photoelectric conversion parts in said plurality of photoelectric conversion parts exhibit spectral sensitivity characteristics that peak in a long-wavelength region with a near-infrared wavelength or longer.

2. The imaging device according to claim 1, wherein said imaging sensor comprises photoelectric conversion parts included in said plurality of photoelectric conversion parts and exhibiting spectral sensitivity characteristics that peak in a visible light region.

3. The imaging device according to claim 1, wherein one of said photoelectric conversion parts corresponds to a pixel in an image image-captured by said imaging sensor, and one of said two pixels arranged adjacent to each other corresponds to said group of photoelectric conversion parts.

4. The imaging device according to claim 1, wherein a set of a plurality of said photoelectric conversion parts corresponds to pixels in an image image-captured by said imaging sensor, and one photoelectric conversion part in the pixels corresponds to said group of photoelectric conversion parts.

5. The imaging device according to claim 1, wherein said group of photoelectric conversion parts comprises photoelectric conversion parts exhibiting spectral sensitivity characteristics that peak in a near-infrared region and photoelectric conversion parts exhibiting spectral sensitivity characteristics that peak in an intermediate-infrared region.

6. The imaging device according to claim 1, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

7. The imaging device according to claim 6, wherein said first material is a group 15 element, and said second material is a group 13 element.

8. The imaging device according to claim 5, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

9. The imaging device according to claim 8, wherein said first material is a group 15 element, and said second material is a group 13 element.

10. The imaging device according to claim 2, wherein said group of photoelectric conversion parts comprises photoelectric conversion parts exhibiting spectral sensitivity characteristics that peak in a near-infrared region and photoelectric conversion parts exhibiting spectral sensitivity characteristics that peak in an intermediate-infrared region.

11. The imaging device according to claim 3, wherein said group of photoelectric conversion parts comprises photoelectric conversion parts exhibiting spectral sensitivity characteristics that peak in a near-infrared region and photoelectric conversion parts exhibiting spectral sensitivity characteristics that peak in an intermediate-infrared region.

12. The imaging device according to claim 4, wherein said group of photoelectric conversion parts comprises photoelectric conversion parts exhibiting spectral sensitivity characteristics that peak in a near-infrared region and photoelectric conversion parts exhibiting spectral sensitivity characteristics that peak in an intermediate-infrared region.

13. The imaging device according to claim 2, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

14. The imaging device according to claim 3, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

15. The imaging device according to claim 4, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

16. The imaging device according to claim 10, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

17. The imaging device according to claim 11, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.

18. The imaging device according to claim 12, wherein
said semiconductor substrate is an n-type Si substrate doped with a first material,
said photoelectric conversion part comprises a pn junction part with said semiconductor substrate as a common semiconductor layer, and
said group of photoelectric conversion parts comprises a p-type semiconductor layer formed by doping at a high concentration said semiconductor substrate with a second material, and during an anneal treatment in which said second material is diffused, light of the long-wavelength region with the near-infrared wavelength or longer is radiated to the p-type semiconductor layer.
